(19) United States
(12) Patent Application Publication
(10) Pub. No.: US 2014/0160646 A1
(43) Pub. Date: Jun. 12, 2014

(54) LATCHING MECHANISM FOR LATCHING A COVER TO A BOTTOM CASING

(71) Applicants: HON HAI PRECISION INDUSTRY CO., LTD., New Taipei (TW); Fu Tai Hua Industry (Shenzhen) Co., Ltd., Shenzhen (CN)

(72) Inventor: Zhan-Sheng LU, Shenzhen (CN)

(73) Assignees: HON HAI PRECISION INDUSTRY CO., LTD., New Taipei (TW); Fu Tai Hua Industry (Shenzhen) Co., Ltd., Shenzhen (CN)

(21) Appl. No.: 13/973,973

(22) Filed: Aug. 22, 2013

(30) Foreign Application Priority Data
Dec. 12, 2012 (CN) 2012105338212

(51) Int. Cl. H05K 5/02; H05K 5/03

(52) U.S. Cl. CPC H05K 5/0221; H05K 5/03
USPC 361/679.01

(57) ABSTRACT

An electronic device includes a latching mechanism for latching a cover to a bottom casing. The latching mechanism includes a slider engaging member and a magnet fixed to an inner side of the cover. The latching mechanism further includes a linkage bar mechanism having two sliders. A first slider is able to move to a position where the slider engaging member interlocks with the first slider, thereby latching the cover to the bottom casing.

### BACKGROUND

1. Technical Field

The present disclosure relates to an electronic device including a latching mechanism for latching a cover to a bottom cover.

2. Description of Related Art

Many electronic devices such as tablet computers include a bottom casing and an upper cover connected to the bottom casing. Many connecting techniques have been proposed for connecting the above elements. However, a new latching mechanism is still needed.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is an isometric view of an electronic device according to one embodiment.

FIG. 2 is an isometric, exploded view of the electronic device of FIG. 1, showing a cover and a bottom casing that are separated from each other.

FIG. 3 is an enlarged view of portion III of FIG. 1.

FIG. 4 is an isomeric, partial view of the cover of FIG. 2, viewed from a different view point.

FIG. 5 is cross-sectional view of the electronic device of FIG. 1 in an unlatched state.

FIG. 6 is similar to FIG. 5, but showing the electronic device of FIG. 1 in a latched state.

### DETAILED DESCRIPTION

Embodiments of the present disclosure will be described with reference to the accompanying drawings.

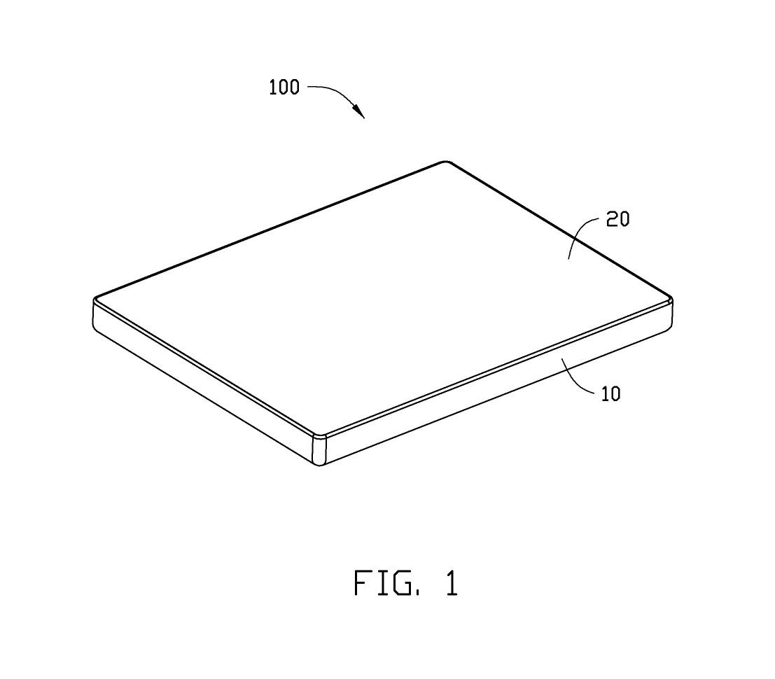

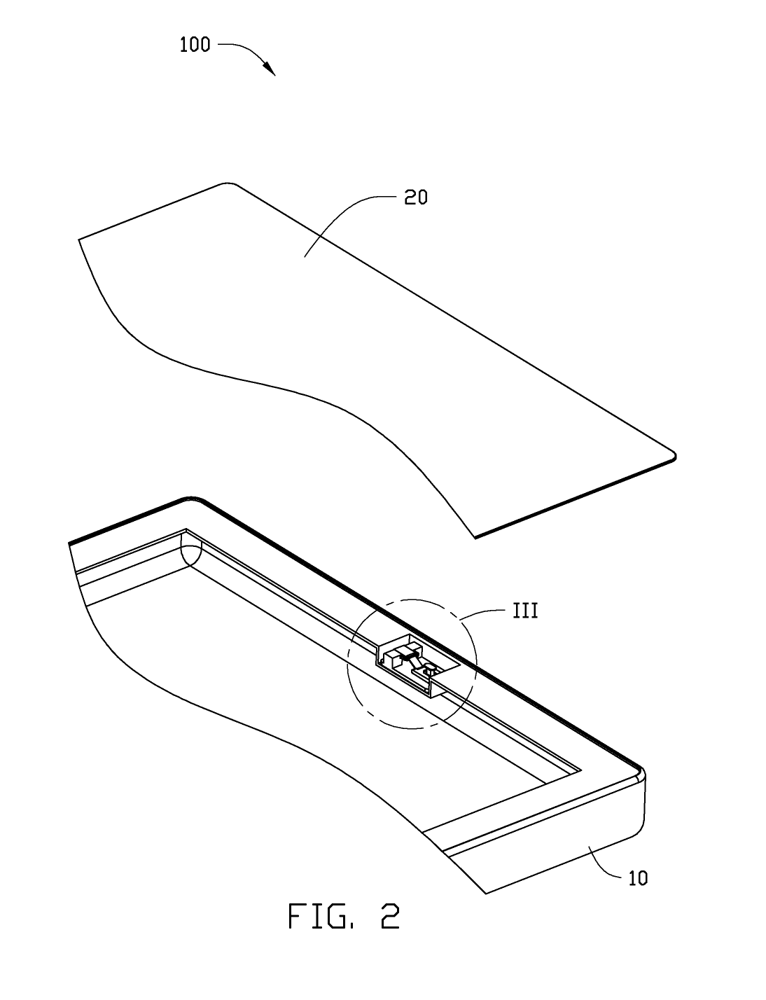

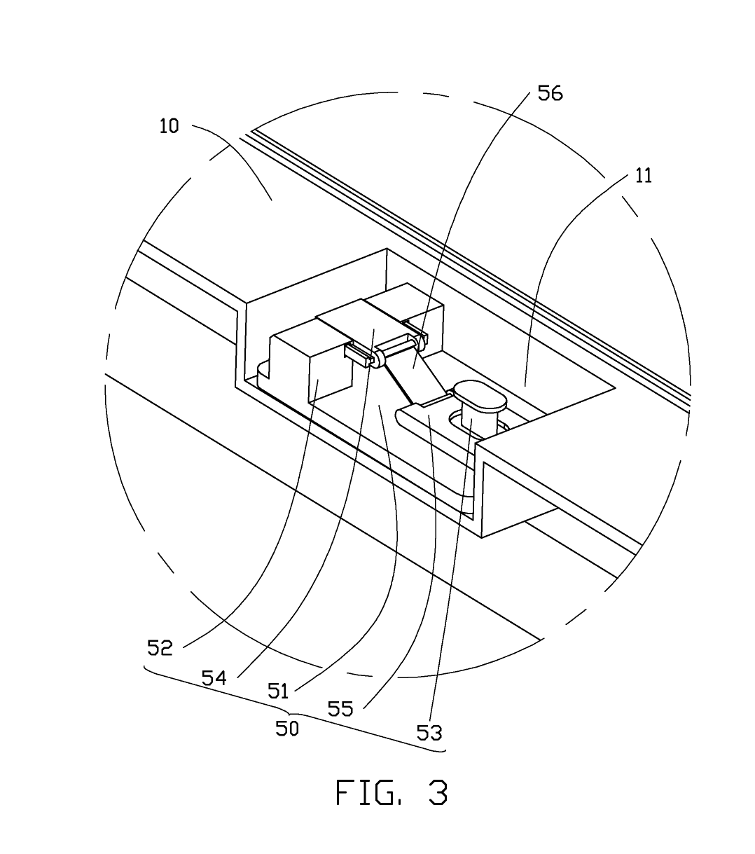

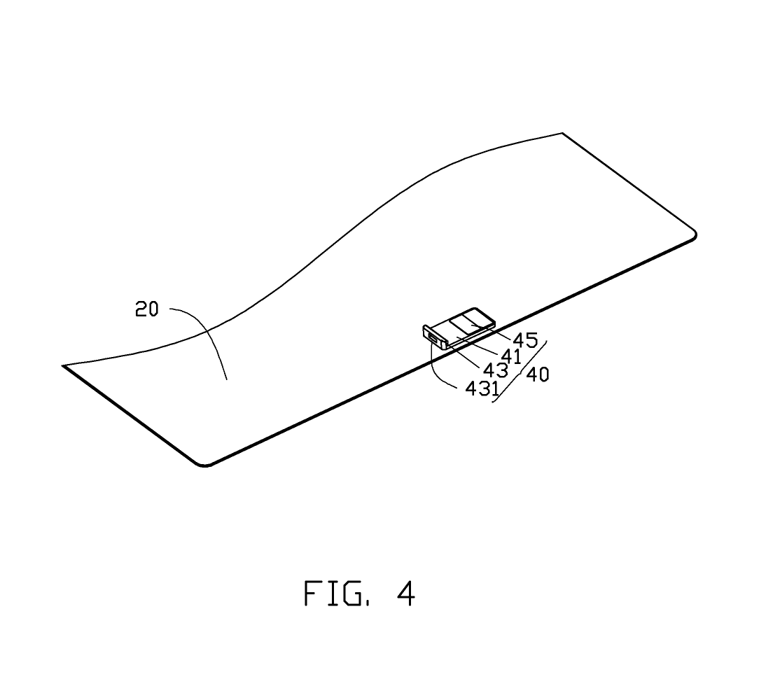

Referring to FIGS. 1-4, an electronic device 100 includes a bottom casing 10, a cover 20, and a latching assembly 30 for latching the cover 20 to the bottom casing 10. The latching assembly 30 includes an upper member 40 and a lower assembly 50.

The upper member 40 includes a main body 41 that includes a surface 411 facing the bottom casing 10, a slider engaging member 43 protruding from the surface 411 at one end, and a magnetic attraction member 45 secured to the surface 411. The slider engaging member 43 defines a slot 431 extending therethrough. In other embodiments, the main body 41 may be omitted, and the slider engaging member 43 may protrude from an inner surface 21 of the cover 20 and the magnetic attraction member 45 may secured to the inner surface 21.

The lower assembly 50 is secured in a cavity 11 defined in a sidewall of the bottom casing 10. The lower assembly 50 includes a base board 51 that is secured in the cavity 11, and includes a first slider guiding member 52 and a second slider guiding member 53 protruding therefrom. The lower assembly 50 further includes a first slider 54, a second slider 55, and a connecting member 56 for connecting the first slider 54 to the second slider 55.

The first slider 54 is slidably connected to the first slider guiding member 52 and slidable along a horizontal direction parallel to the planar surface where the first slider guiding member 52 protrudes. In the embodiment, the first slider guiding member 52 includes two spaced blocks, each of which defines a slot. The first slider 54 includes two opposite sliding rails that are slidably received in the two slots of the slider guiding member 52.

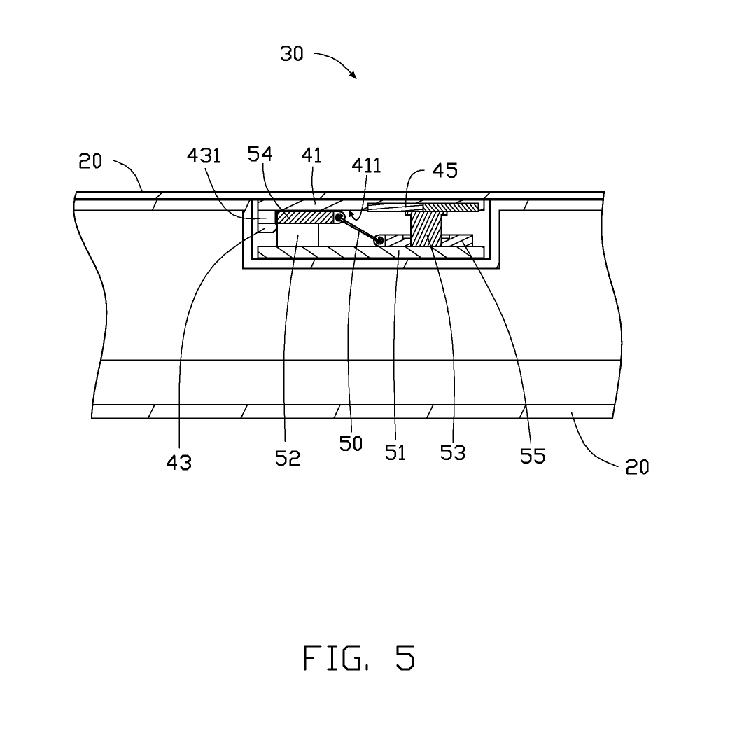

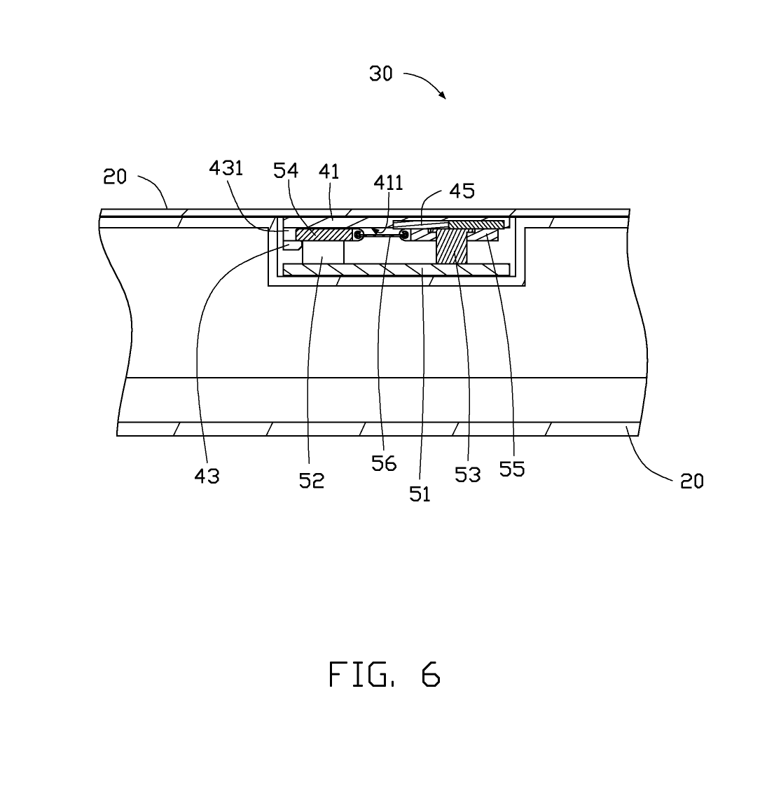

The second slider 55 is slidably connected to the second guiding member 53 and slidable along a vertical direction perpendicular to the planar surface where the first slider guiding member 53 protrudes. In the embodiment, the second slider guiding member 53 is a vertical bar protruding from the planar surface where the first slider guiding member 53 protrudes. The second slider 55 defines a slot, through which the second slider guiding member 53 passes, thereby allowing the second slier 55 to slide along the second slider guiding member 53. The second slider 55 is magnetic attractable to the magnetic attraction member 45, and can slide from a lowermost position show in FIG. 5 to an uppermost position shown in FIG. 6 because of magnetic attraction of the magnetic attraction member 45.

The connecting member 56 includes opposite ends that are pivotally connected to ends of the first slider 54 and the second slider 55. When the second slider 55 slides from a lowermost position show in FIG. 5 to an uppermost position shown in FIG. 6, the connecting member 56 moves as urged by the second slider 55, and pushes the first slider 54 to move from an original position shown in FIG. 5 to a locking position shown in FIG. 6, where the first slider 54 interlocks with the slider engaging member 43. That is, the free end of the first slider 54 is fit into the slot 431 of the slider engaging member 43, thereby latching the cover 20 to the bottom casing 10.

In the embodiment, the magnetic attraction member 43 is a magnet, and the second slider 55 is a metal block. In other embodiments, the second slider 55 may be magnet. In this case, the second slider 55 can slide away from the magnetic attraction member 43 by a repelling force of an external magnet. The connecting member 56 then pulls the first slider 54 away from the slider engaging member 43, thereby allowing the cover 20 to be removed from the bottom casing 10. In yet another embodiment, the first slider 54 may be a magnet, and can be caused to move away form the slider engaging member 43 by a repelling force of an external magnet.

While various embodiments have been described and illustrated, the disclosure is not to be construed as being limited thereto. Various modifications can be made to the embodiments by those skilled in the art without departing from the true spirit and scope of the present disclosure as defined by the appended claims.

What is claimed is:

1. An electronic device comprising:
a bottom casing comprising a sidewall that defines a cavity;
a cover connected to the bottom casing and comprising an inner side facing the bottom casing; and
a latch assembly comprising:
a slider engaging member and a magnetic attraction member secured to the inner side of the cover;
a base board secured in the cavity of the bottom casing and comprising a first slider guiding member and a second slider guiding member;
a first slider slidably connected to the first slider guiding member, the first slider being slidable along a first direction;
a second slider slidably connected to the second slider guiding member, the second slider being slidable along a second direction to an attaching position where the second slider magnetically attached to the magnetic attraction member; and
a connecting member comprising opposite ends pivotally coupled to the first slider and the second slider, when the second slider slides to the attaching position, the connecting member being driven by the second slider to push the first slider to slide to a locking position where the first slider interlocks with the slider engaging member, thereby latching the cover to the bottom casing.

2. The electronic device according to claim 1, wherein the slider engaging member protrudes from the inner side of the cover and defines a slot to receive a free end of the first slider when the first slider slides to the locking position.

3. The electronic device according to claim 1, wherein the magnetic attraction member is a magnet, and the second slider is a metal block.

4. The electronic device according to claim 1, wherein the first slider is a magnet.

5. The electronic device according to claim 1, wherein the first direction is parallel to the base board, the second direction is perpendicular to the base board.
